(19) United States
(12) Patent Application Publication
(10) Pub. No.: US 2013/0337603 A1
(43) Pub. Date: Dec. 19, 2013

(54) METHOD FOR HYDROGEN PLASMA TREATMENT OF A TRANSPARENT CONDUCTIVE OXIDE (TCO) LAYER

(71) Applicant: TEL Solar AG, Trubbach (CH)

(72) Inventors: Jerôme Steinhauser, La chaux de Fonds (CH); Daniel Borrello, Cortaillod (CH)

(21) Appl. No.: 13/920,907

(22) Filed: Jun. 18, 2013

Related U.S. Application Data
(60) Provisional application No. 61/660,961, filed on Jun. 18, 2012.
(60) Provisional application No. 61/671,866, filed on Jul. 16, 2012.
(60) Provisional application No. 61/660,893, filed on Jun. 18, 2012.

(51) Int. Cl. H01L 31/076

(52) U.S. Cl. CPC H01L 31/076
USPC 438/96

(57) ABSTRACT

A method for fabricating a thin film solar device that includes providing a substrate having a transparent conductive oxide (TCO) layer deposited on a surface of the substrate, the TCO layer having an as deposited sheet resistance. At least a portion of a surface of the TCO layer is exposed to a hydrogen plasma under conditions which result in a treated TCO layer having a reduced sheet resistance which is at least 10% less than the as deposited sheet resistance.

### CROSS-REFERENCE TO RELATED APPLICATIONS

This application claims priority to Application Ser. No. U.S. 61/660,893, filed Jun. 18, 2012 (TES-129US), U.S. 61/671,866, Jul. 16, 2012 (TES-129US-1) and U.S. 61/660,961, filed Jun. 18, 2012 (TES-132-PRO). The entire content of each of these applications is incorporated by reference herein.

### BACKGROUND

1. Technical Field

Embodiments disclosed herein generally relate to forming photovoltaic (PV) devices, and more particularly to forming transparent conductive oxide (TCO) layers used as front and/or back electrodes of a PV device.

2. Background Art

Photovoltaic devices, or solar cells, are devices which convert light into electrical power. Thin-film solar cells nowadays are of a particular importance since they have a huge potential for mass production at low cost. Typically, a thin-film solar cell includes an amorphous and/or microcrystalline silicon film having a PIN (or NIP) junction structure arranged in parallel to the thin-film surface and sandwiched between transparent film electrodes.

Thin-film solar cells are typically combined in panels or modules to provide a device having desired power output, for example. A method for manufacturing thin-film solar modules provides a stack on a substrate of glass or other suitable material. The stack generally includes a first electrode (front electrode), a semiconductor layer and a second electrode (back electrode) sequentially formed on the substrate. Each of these layers is typically formed by a multi-step production process which may include forming multiple layers.

It is well known that processes used in the production of commercial thin-film silicon photovoltaic modules should maximize module power and at the same time minimize production costs. Thus, advances in mass production of thin-film solar cells at low cost may be hampered by resulting drawbacks in module performance.

### SUMMARY

One object of embodiments of the invention is to maximize thin-film solar module output power without substantial increase in production costs.

Another object of embodiments of the invention is to minimize production costs for thin-film solar modules without substantial decrease in module power output.

These and/or other objects and advantages may be realized by embodiments of the invention disclosed herein.

For example, one non-limiting embodiment of the present invention provides a method for fabricating a thin film solar device. The method includes providing a substrate having a transparent conductive oxide (TCO) layer deposited on a surface of the substrate, the TCO layer having an as deposited sheet resistance. At least a portion of a surface of the TCO layer is exposed to a hydrogen plasma under conditions which result in a treated TCO layer having a reduced sheet resistance which is at least 10% less than the as deposited sheet resistance.

### BRIEF DESCRIPTION OF THE DRAWINGS

The accompanying drawings, which are incorporated in and constitute a part of the specification, illustrate one or more embodiments and, together with the description, explain these embodiments. The accompanying drawings have not necessarily been drawn to scale. Any values dimensions illustrated in the accompanying graphs and figures are for illustration purposes only and may or may not represent actual or preferred values or dimensions. Where applicable, some or all features may not be illustrated to assist in the description of underlying features. In the drawings:

FIG. 1 illustrates a tandem junction silicon thin-film solar cell in accordance with embodiments of the invention.

FIG. 2 illustrates a top view of a thin-film silicon module in accordance with embodiments of the invention.

FIG. 3 illustrates an example of a simple TCO multilayer system in accordance with embodiments of the invention.

FIG. 4 is an atomic force miscroscopy (AFM) scan showing surface texture of a standard ZnO layer which may provide a base layer in accordance with embodiments of the invention.

FIGS. 5A and 5B are AFM scans showing surface structures of a ZnO layer having fill layers in accordance with an embodiment of the invention.

FIG. 6 is a graph showing the effect of increasing the number of fill layers on cell Voc in accordance with embodiments of the invention.

FIG. 7 is a graph showing the effect of increasing the number of fill layers on cell Fill Factor in accordance with embodiments of the invention.

FIG. 8 is a graph showing results of experiments performed to determine optimum water to Diborane ratio in accordance with embodiments of the invention.

FIG. 9 is a simplified sketch depicting a thin-film cell having decreasing thickness fill layers in accordance with embodiments of the invention.

FIG. 10 is a graph showing the free electron mobility and the free carrier density of a LPCVD ZnO film as a function of the hydrogen plasma exposure time in accordance with embodiments of the invention.

FIG. 11 is a graph showing the infrared reflectance of a LPCVD deposited ZnO film before and after hydrogen plasma exposure in accordance with embodiments of the invention.

### DESCRIPTION OF EMBODIMENTS

The description set forth below in connection with the appended drawings is intended as a description of various embodiments of the invention and is not necessarily intended to represent the only embodiment or embodiments in which the invention may be practiced. In certain instances, the description includes specific details for the purpose of providing an understanding of the invention. However, it will be apparent to those skilled in the art that the invention may be practiced without these specific details. In some instances, some structures and components may be shown in block diagram form in order to avoid obscuring the concepts of the disclosed subject matter.

Additionally, it is noted that, as used in the specification and the appended claims, the singular forms “a,” “an,” and “the” include plural referents unless the context clearly dictates otherwise. That is, unless clearly specified otherwise, as used herein the words “a” and “an” and the like carry the meaning of “one or more.” Further, it is intended that the present invention and embodiments thereof cover the modifications and variations. For example, it is to be understood that terms such as “left,” “right,” “top,” “bottom,” “front,” “rear,” “side,” “height,” “length,” “width,” “upper,” “lower,” “interior,” “exterior,” “inner,” “outer,” and the like that may be used herein, merely describe points of reference and do not limit the present invention to any particular orientation or configuration. Furthermore, terms such as “first,” “second,” “third,” etc., merely identify one of a number of portions, components, steps, and/or points of reference as disclosed herein, and likewise do not limit the present invention to any particular configuration, orientation, number, or order.

The following definitions are provided to facilitate understanding of the description provided herein:

Processing in the sense of this invention includes any chemical, physical or mechanical effect acting on substrates.

Substrates in the sense of this invention are components, parts or workpieces to be treated in a processing apparatus. Substrates include but are not limited to flat, plate shaped parts having rectangular, square or circular shape. In a preferred embodiment this invention addresses essentially planar substrates of a size >1 m2, such as thin glass plates.

A vacuum processing or vacuum treatment system or apparatus comprises at least an enclosure for substrates to be treated under pressures lower than ambient atmospheric pressure.

CVD Chemical Vapor Deposition is a well known technology allowing the deposition of layers on heated substrates. A usually liquid or gaseous precursor material is being fed to a process system where a thermal reaction of said precursor results in deposition of said layer. LPCVD is a common term for low pressure CVD.

DEZ—diethyl zinc is a precursor material for the production of TCO layers in vacuum processing equipment.

TCO stands for transparent conductive oxide, TCO layers consequently are transparent conductive layers. The terms layer, coating, deposit and film are interchangeably used in this disclosure for a film deposited in vacuum processing equipment, be it CVD, LPCVD, plasma enhanced CVD (PECVD) or PVD (physical vapor deposition).

A solar cell or photovoltaic cell (PV cell) is an electrical component, capable of transforming light (essentially sun light) directly into electrical energy by means of the photoelectric effect.

A thin-film solar cell in a generic sense includes, on a supporting substrate, at least one p-i-n junction established by a thin-film deposition of semiconductor compounds, sandwiched between two electrodes or electrode layers. A p-i-n junction or thin-film photo-electric conversion unit includes an intrinsic semiconductor compound layer sandwiched between a p-doped and an n-doped semiconductor compound layer. The term thin-film indicates that the layers mentioned are being deposited as thin layers or films by processes like, PEVCD, CVD, PVD or alike. Thin layers essentially mean layers with a thickness of 10 μm or less, especially less than 2 μm.

Diborane—Technically B₂H₆ (boron dopant) is available as a gas mixture of 2% B2H6 in hydrogen. Within the context of this disclosure the doping ratios are based on said technical gas mixture and the term “boron” or B₂H₆ means said technical gas mixture.

Haze is defined as the ratio of transmitted scattered light to the total transmitted light. Haze can be measured using a spectro-photometer equipped with an integrating sphere. In this text, haze refers to haze at a wavelength of 600 nm if not otherwise specified.

FIG. 1 illustrates a tandem junction silicon thin-film solar cell in accordance with embodiments of the invention. Such a thin-film solar cell 50 usually includes a first or front electrode 42, one or more semiconductor thin-film p-i-n junctions (52-54, 51, 44-46, 43), and a second or back electrode 47, which are successively stacked on a substrate 41. Each p-i-n junction 51, 43 or thin-film photoelectric conversion unit includes an i-type layer 53, 45 sandwiched between a p-type layer 52, 44 and an n-type layer 54, 46 (p-type=positively doped, n-type=negatively doped). Substantially intrinsic in this context is understood as not intentionally doped or exhibiting essentially no resultant doping. Photoelectric conversion occurs primarily in this i-type layer; it is therefore also called absorber layer.

Depending on the crystalline fraction (crystallinity) of the i-type layer 53, 45 solar cells or photoelectric (conversion) devices are characterized as amorphous (a-Si or α-Si, 53) or microcrystalline (mc-Si or μc-Si, 45) solar cells, independent of the kind of crystallinity of the adjacent p and n-layers. Micro-crystalline layers are being understood, as common in the art, as layers comprising of a significant fraction of crystalline silicon—so called micro-crystallites—in an amorphous matrix. Stacks of p-i-n junctions are called tandem or triple junction photovoltaic cells. The combination of an amorphous and micro-crystalline p-i-n-junction, as shown in FIG. 1, is also called micromorph tandem cell.

Tandem solar cells based on a-Si:H and mc-Si:H are usually deposited on front contacts made of tin oxide (SnO₂) or zinc oxide (ZnO). ZnO can be produced by sputtering or by LPCVD. Usually sputtered ZnO is then wet-etched to obtain a rough surface which scatters light. On the contrary, layers of LPCVD ZnO are constituted of several pyramidal structures with size ranging from few nm to several 100 nm. That is, a LPCVD ZnO layer is generally rough and its roughness can be partially controlled modifying process parameters. Surface roughness (or surface texture) causes light scattering and a simple method to measure light scattering is to measure haze.

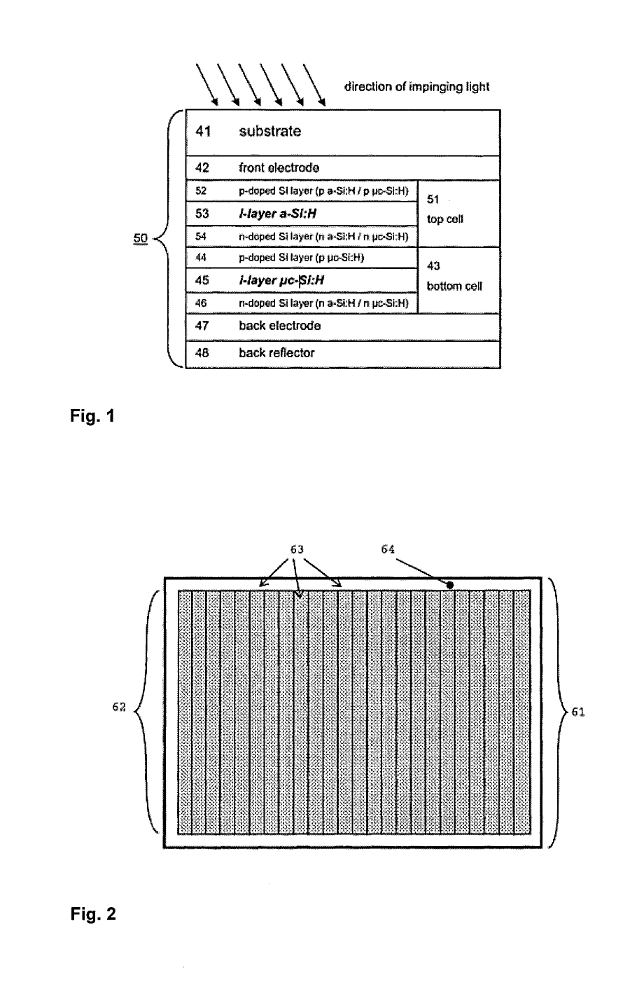

As noted in the Background section, thin-film solar cells are often combined in panels and/or modules. FIG. 2 illustrates a top view of a thin-film silicon module in accordance with embodiments of the invention. The production of thin-film silicon modules involves several steps. Normally, as a first step a TCO layer is applied as front electrode 42, and subsequently silicon layers (52-54), on a glass substrate 41 (or comparable materials). This coating step affects the whole surface of a panel 61. This panel 61 however includes an active area 62 with the photovoltaically active layers with cells (such as those of FIG. 1. 63 electrically connected in series and/or parallel. To ensure electrical insulation, the edge area 64 of each module or panel 61 is cleaned of all TCO and silicon layers and then modules can be laminated to protect them from weathering. The edge area thus provides a barrier for environmental influences to negatively affect the sensitive active cells 63 in the active area 62. Such “edge isolation” may be performed by mechanical removal of the layers in the edge area 64 by using abrasives, e.g. by sandblasting or similar techniques, or by using a laser beam by removing (ablation and/or vaporization) the silicon and ZnO layers due to absorption of laser energy in the layers. Further details of edge isolation processes have been described in U.S. Provisional Patent Application Ser. Nos. 61/262,691, 61/434,022 and 61/512,074, each of which is incorporated by reference herein in its entirety.

The performance of thin-film silicon cells and modules is strongly influenced by the properties of the first TCO layer(s) (front contact 42, FIG. 1). Relevant properties of the TCO to be considered are total transmission, haze and conductivity. In common TCO based on LPCVD ZnO these three parameters can be varied by modifying the amount of dopant gas (usually Diborane, B₂H₆) added to the precursor gases during growth in a LPCVD process. When the complete layer is made using one single set of gas flows and the layers thickness is kept constant, it is known in the art increasing the doping amount reduces haze, reduces total transmission of red and NIR light and increases conductivity; decreasing the doping amount leads to the inverse effects. Best module performance is obtained by increasing total transmission, increasing haze and increasing conductivity: obviously it is not possible to achieve all these goals in a single layer system. For example, a common tradeoff to improve module performance is therefore to reduce the doping level of TCO to improve total transmission and haze by accepting a certain loss of conductivity.

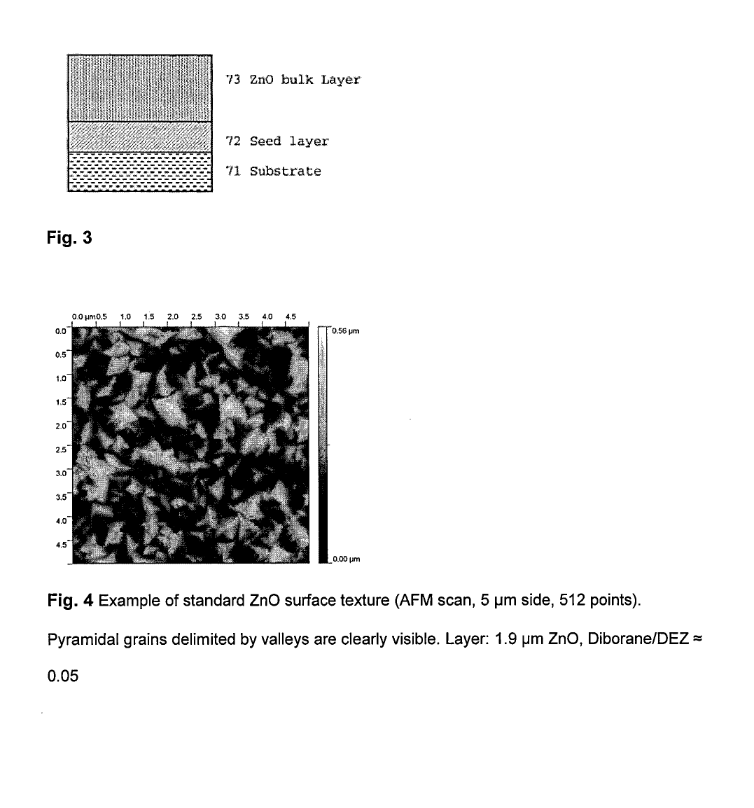

Multilayered TCO systems have been developed to control the characteristics of a TCO layer for a particular implementation. FIG. 3 illustrates an example of a simple TCO multilayer system in accordance with embodiments of the invention. As seen, the system includes a first ZnO layer (identified as seed layer 72) deposited on a substrate 71, preferably glass, and a second layer (identified as bulk layer 73) deposited on the seed layer. The first ZnO layer may be strongly doped with boron to enhance conductivity of the TCO and to support laser edge processing of the module (discussed above). An example process for realizing such a strongly doped layer would be:
B₂H₆/DEZ ratio: of 0.1 to 2, preferred range 0.2 to 1, more preferred range 0.2 to 0.6;
Temperature of glass: 150-220° C., preferred range 180-195° C.;
H₂O/DEZ ratio: 0.8 to 1.5; and
Thickness: less than 300 nm, preferred thickness is 50 nm to 200 nm.

The bulk layer 73 may be lowly doped to provide haze and to keep absorption low, thus increasing the current generated in the microcrystalline cell. An example process for realizing such a lowly doped layer would be:
B₂H₆/DEZ ratio: 0.01 to 0.2, best range 0.02 to 0.1;
Temperature of the glass during deposition step: 150-220° C., best range 180-195° C.;
H₂O/DEZ ratio: 0.8 to 1.5; and
Thickness from 500 nm to several micrometers, good range 900 nm to 3 μm, best results with no more than 2 μm total thickness.

The multilayer TCO structure may have an additional layer provided as an interlayer between the glass substrate 71 and the first highly doped seed layer 72. Further, varying process parameters and repeating process steps may achieve different implementations of the multilayer structure. Further details of these variations are disclosed in U.S. Provisional Application Nos. 61/434,022 and 61/512,074 each incorporated herein by reference.

As noted in the Background, processes used in the production of commercial thin-film silicon photovoltaic modules should maximize module power while minimizing production costs. In this regard, one drawback in the production process recognized by the present inventors is that cells based on microcrystalline Silicon (including Tandem cells) are usually sensitive to the substrate where they are grown. Using the same growth parameters, a microcrystalline cell deposited on sputtered-etched ZnO is usually electrically better than a cell deposited on LPCVD ZnO. Cells deposited on sputtered-etched ZnO have usually a higher open circuit voltage (Voc) and Fill-Factor (FF) than cells deposited on LPCVD ZnO. Short circuit current is usually lower on sputtered-etched ZnO than on LPCVD ZnO for the same cell thickness. The silicon cell deposition process can be tuned to be better suited to a specific material of the TCO, producing better cell result; however, the differences in FF and Voc can usually not be completely compensated by such tuning. Additionally, cells deposited on LPCVD ZnO often show structural defects (“cracks”) which can not be completely eliminated by process tuning.

The growth mechanism and the reason for different cell characteristics on different types of TCO are not fully understood. One common interpretation is related to surface texture. For example, in LPCVD ZnO the surface is covered with pyramids as shown in FIG. 4 (disclosed below). Between each pyramid are V-shaped valleys and the solar cell material will be deposited inside these valleys. Due to the valley cross-section (V), material growing from the two opposing sides will meet approximately in the middle. In several cases a “crack” appears at this meeting point. Such cracks are clearly visible in cross section of cells on LPCVD ZnO observed by SEM or TEM.

In the case of sputtered-etched ZnO, the surface texture resembles rounded, U-shaped craters and the lateral size of such craters is usually much larger than the valley size. Cracks do not usually form on sputtered-etched ZnO. However, LPCVD ZnO can be usually produced at lower cost than sputter-etched ZnO. Therefore, the inventors recognized that it is commercially important to find low cost methods for producing surface texture modifications which allow a better cell growth. One proposed solution is to work on LPCVD ZnO which has been treated by Ar-plasma etching to smooth its surface texture as described in the paper by M. Python et al. (M. Python et al. Journal of non-crystalline solids, vol. 354, 2008, 5 p. 2258-2262), the contents of which are incorporated herein by reference. In this case, the cell performance is similar to cells deposited on sputter-etched ZnO substrates. However, the present inventors recognized that such a solution requires an additional tool and it is not production friendly.

Alternatively, one embodiment of the invention suggests a surface texture based on LPCVD ZnO which is optimal for the growth of microcrystalline and micromorph thin-film silicon solar cells. Generally, a starting point for this embodiment is a thick ZnO layer, called a “base layer”. The exact properties of this layer are not very important, and the base layer may be implemented as a simple single layer, or as a multilayer system as discussed above. The base layer(s) should provide a large enough haze for light scattering, and may be a simple ZnO single layer. Alternative possible realizations of such a base layer are described in patent applications U.S. 61/512,074 and U.S. 61/434,022 each incorporated by reference herein.

FIG. 4 is an atomic force miscroscopy (AFM) scan showing surface texture of a standard ZnO layer which may provide a base layer in accordance with embodiments of the invention. The ZnO layer of FIG. 4 is 1.9 μm ZnO, Diborane/DEZ≈0.05. As seen, pyramidal grains delineated by valleys are clearly visible. The base layer will generally have a surface texture mostly consisting of pyramids, and tandem cells deposited on this surface would show structural defects (“cracks”) in the microcrystalline bottom cell. Adjacent pyramids will be delimited by valleys with a V profile, these valleys will induce the formation of “cracks” in microcrystalline silicon layers.

According to embodiments of the invention, several layers of nanocrystalline ZnO (called “fill layers”) are deposited on top of this base layer. Such finely grained ZnO is able to fill deep valleys and to qualitatively smooth the underlying surface. A simplified representation of such layers is shown in FIG. 9 (discussed below). In general the fill layers will have small grained structures with grain sizes smaller than that of the base layer.

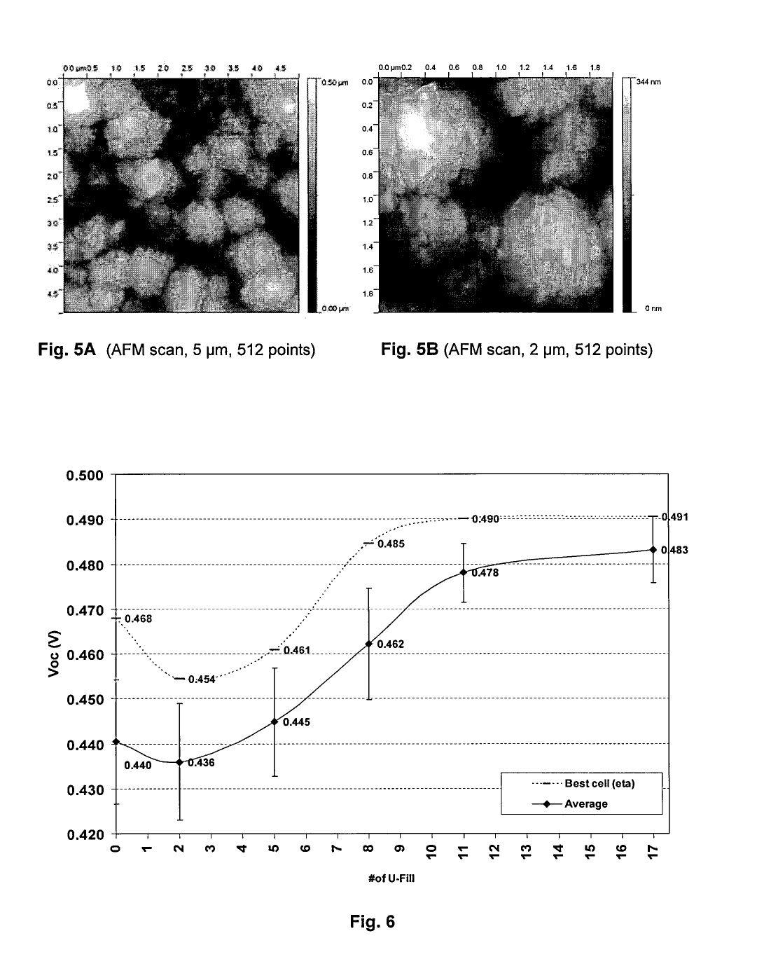

FIGS. 5A and 5B are AFM scans showing the surface structure of a ZnO layer having fill layers in accordance with an embodiment of the invention. The example ZnO layer has the following layer structure:
seed layer: 150 nm with Diborane/DEZ≈0.5;
bulk layer, together with seed: base layer: 2 μm with Diborane/DEZ≈0.05
Diborane surface treatment: 11 layers of approx. 80 nm each, Diborane/DEZ≈0.05, each separated by a Diborane surface treatment.

As seen in FIGS. 5A and 5B, the resulting surface texture qualitatively looks like “cauliflowers” and seems “rounded.” This qualitative description is based on limited resolution of the measurement. Specifically, in FIG. 5A, at 5 μm width, it is clearly possible to identify large structures, lateral size up to 2000 nm. Such structures originate from the underlying base layer and can be made larger or smaller by changing the base layer properties. Fill layers will enlarge the size of big structures; additionally fill layers produce finely grained superstructures already visible in FIG. 5A. FIG. 5B is an AFM scan showing the example ZnO layer of FIG. 5A at different resolution. As seen in FIG. 5B, at 2 μm width, it is still possible to see a few of the large structures noted above, additionally it is possible to see smaller structures of less than 200 nm lateral size all over the surface. These small structures may later be covered by amorphous silicon and this additional layer will smooth the surface even more.

Comparing FIG. 4 with FIGS. 5A, 5B clearly shows the difference between conventional ZnO layers (which may provide a base layer) and ZnO layers obtained according to embodiments of the invention.

Embodiments of the invention further suggests a method to produce LPCVD ZnO with a surface texture as described above, which allows to improve microcrystalline silicon cells (less structural defects, more Voc, more FF). Especially, narrow valleys which induce the formation of structural defects (“cracks”) in the microcrystalline material are avoided or minimized.

As noted above, the starting point for this invention may be a thick ZnO layer, called “base layer,” and the exact properties of this layer are not very important. Possible thicknesses for the base layer are 1 μm to 4 μm or even more. A useful range is probably 1.6 μm to 3 μm. The base layer(s) should provide a large enough haze for light scattering.

According to embodiments of the invention, on top of this layer(s), several thinner ZnO layers are deposited to produce very finely grained ZnO called “Nanocrystalline ZnO”. Nanocrystalline ZnO can be obtained by applying a surface treatment based on Diborane before starting the deposition of a new ZnO layer. Such treatment generally includes stopping DEZ flow, introducing Diborane for a few seconds, and continuing deposition. Diborane treatment is described in more detail in U.S. 61/379,917 and derived applications such as PCT/EP2011/065134 and TW 100131746 and U.S. Ser. No. 13/819,949, which are incorporated herein by reference in their entirety. In general, Nanocrystalline ZnO layers will have small grained structures and the grain size can be controlled by the deposition time (or equivalent layer thickness). Longer deposition will lead to larger grains. Using several layers (2 to 15) produces an optimal ZnO surface suitable for optimal growth on tandem cells as described above. Moreover, optimization of the layer structure may be obtained by one or more of:

1. Modifying the properties of the base layer (thickness, doping, haze, Water/DEZ ratio used during deposition, etc.);

2. Modifying the thickness of each fill layer;

3. Modifying the number of fill layers;

4. Modifying the doping of each fill layer; or

5. Modifying the Water/DEZ ratio used during deposition of each fill layer.

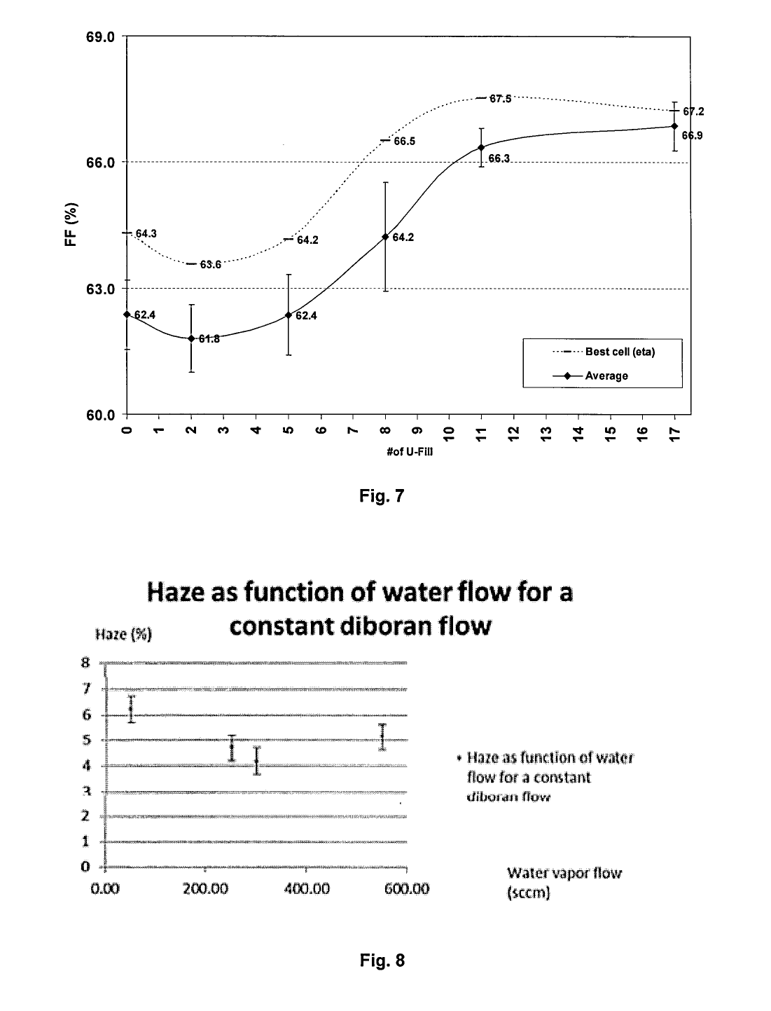

FIGS. 6 and 7 illustrate the effect of increasing the number of fill layers in accordance with embodiments of the invention. In these cases, microcrystalline cells were produced on a conductive a-Si layer used to simulate a top cell absorption but without voltage and current generation. Such an amorphous silicon layer is generally called “Filter a-Si layer”. The graphs relate to the following layer structure:
seed layer: 150 nm with Diborane/DEZ≈0.5;
bulk layer or base layer: 2 μm with Diborane/DEZ≈0.05; and
Diborane surface treatment: 2 to 17 layers of approx. 80 nm each, Diborane/DEZ≈0.05, each separated by a Diborane surface treatment.

FIG. 6 is a graph showing the effect of increasing the number of fill layers (all of the same thickness) on cell Voc in accordance with embodiments of the invention. It is clearly visible in FIG. 6 that increasing the number of fill layers improves the Voc of microcrystalline cells. All cells are deposited at the same deposition parameters. It is noted that the Front Contact used for the data point with 0 fill layers in FIG. 6 is thinner (i.e, less rough) than the base layer used in all other experiments.

FIG. 7 is a graph showing the effect of increasing the number of fill layers (all of the same thickness) on cell Fill Factor in accordance with embodiments of the invention. It is clearly visible that increasing the number of fill layers improves the FF of microcrystalline cells. All cells are deposited using the same deposition parameters.

The approach presented herein is very broad. Generally, embodiments of the invention include providing a substrate having a base layer, teating the base layer and forming one or more fill layers on the treated base layer. The inventive concept is being described with the aid of several embodiments. In general the doping ratio or doping level of the ZnO layers is not relevant to the surface treatment effect of embodiments of the invention. However, similar to the discussion above, changing the doping levels in each layer allows optimizing the whole structure for improved sheet resistance and improved total transmission, for example. A key component of embodiments of the invention is a surface treatment to re-start growth of LPCVD ZnO from new grains, combined with optimized thickness of the fill-layers layers.

While the embodiments discussed below relate to front contacts of a thin-film solar cell, all mentioned approaches can be used for back contacts too.

The following embodiments have been realized in a TCO 1200 deposition system (manufactured by Oerlikon Solar AG) equipped with 2 process modules (PM1 and PM2) and Load/Unload Locks (LL). Other, comparable systems may be used without deviating from the invention. The number of PM shall not be limiting, it may be less or more. All steps addressing handling, moving, heat-up times, etc. may be system specific and thus may be realized differently; however this does not affect general surface treatment aspect of the invention.

Glasses as addressed below are workpieces from glass with 1100×1300 mm² size. Volume or flow based specifications refer to this size and thus may be scaled up and down to match respective other substrate or workpiece sizes. Temperatures mentioned are temperatures set on respective heating systems or measured. A variation of +−5% shall be regarded as included in the inventive set of parameters. Flows mentioned are the ones set or measured at respective valves or Mass-flow-controllers. A deviation of +−5% shall be regarded as included in the inventive set of parameters. Time in seconds may be denoted by “s.”

One process which implements embodiment of the invention includes the following steps:

1. Clean glasses are loaded sequentially in Load Lock (LL).

2. In LL a first glass is heated to approximately 180° C. (160° C. to 200° C.).

3. First glass is transferred from LL to PM1.

4. Second glass is loaded into LL and heated.

5. Second glass is transferred from LL to PM1, and first glass is transferred from PM1 to PM2.

6. Glasses wait on hotplate at nominal temperature of 182° C. for 600 s under H₂ flow (1000 sccm) and H₂O flow (1170 sccm).

7. Gas mixture for “seed layer” is let into PM1 and PM2 as follows: 960 sccm DEZ, 1170 sccm H₂O, 360 sccm Diborane, 270 sccm H₂, pressure is regulated to 0.5 mbar using Nitrogen.

8. Deposition time for the “seed layer”: 50 s.

9. Gas mixture for “bulk layer” is let into PM1 and PM2 as follows:

960 sccm DEZ, 1170 sccm H₂O, 55 sccm Diborane, 270 sccm H₂, pressure may change due to changes of gas flows.

10. Deposition time for “bulk layer”: 1000 s.

11. Treatment as follows: DEZ Flow is stopped, Diborane flow is set to 360 sccm, pressure may change due to changes of gas flows.

12. Treatment time: 40 s.

13. Gas Mixture for “fill layer” is let into PM1 and PM2 as follows: 960 sccm DEZ, 1170 sccm H₂O, 55 sccm Diborane, 270 sccm H₂, pressure may change due to changes of gas flows.

14. Deposition time for “fill layer”: 33 s.

15. Steps 12 to 15 are repeated 10 times (total: eleven executions of steps 12 to 15), and gas flows are stopped after last execution.

16. First glass is transferred from PM2 into Unload lock, second glass is transferred from PM1 to PM2, a new glass may be loaded from LL to PM1 (and heated as in step 3).

17. First glass is removed from machine.

18. Second glass is transferred from PM2 into Unload Lock, a new glass may be loaded from LL to PM1 (and heated as in step 3); if a glass is present in PM1 (loaded at step 17) it will be transported to PM2.

19. Second glass is removed from machine.

The procedure may be repeated from step 6.

In the example above, surface treatment occurs in steps 11 and 12. A general example procedure to restart growth of a ZnO layer on a previously deposited ZnO layer (based on 1.4 m² glass substrate) in a LPCVD process environment, named hereinafter as “Diborane treatment”, is now described. It is to be noted that “Diborane” as mentioned herein means the commercially available Diborane gas mixture of 2% B₂H₆ in hydrogen. The Diborane treatment may generally include the following steps, with variations noted.

Step 1 of the treatment process is to stop the DEZ flow in the process chamber. Other process gases like Diborane, H₂O, H₂, N₂ may be stopped too.

Step 2 is to reduce the DEZ concentration in the deposition chamber by pumping or purging. Pump the chamber to pressure of approximately ½ of the usual process pressure or less, i.e. 0.2 mbar to 0.1 mbar. Depending on the performance of the installed pumps, the pumping time will be around 60 s or less. Alternatively, any remaining DEZ from previous process steps may be removed by purging the chamber using other process gases (like Diborane, H₂O, H₂, N₂, etc). Purging for 60 s with 400 sccm H₂O has been shown to be sufficient. Larger purging gas flows allow to shorten this step.

Step 3 introduces Diborane and H₂O into the process chamber, where the substrate is located. A successful treatment for a commercially available TCO 1200 system (Oerlikon Solar) for 1.4 m² substrates uses 550 sccm H₂O, 150 sccm Diborane (for one single treatment chamber), plus optionally hydrogen. This is a water/Diborane flow ratio of about 3.7. Exposure of the substrate to said gas mixture for at least 60 seconds is sufficient. A quicker treatment suitable for production uses 1000 sccm H₂O and 375 sccm Diborane (ratio water/Diborane 2.7), in this case only 15 s are necessary to achieve a successful treatment. Usually treatments are performed without explicit pressure control (pressure is set at start of deposition process, then it will change depending on the total gas flows but will remain approximately at the original setting of 0.5 mbar). To make the treatment process economically more attractive, it is possible to increase the pressure during Diborane treatment. Using a working pressure of 3 mbar allows to further reduce the treatment time to 10 s. Experiments have shown that a treatment of several minutes (5-20) is possible, for economic reasons, however one will try to limit the exposure. It is to be noted that this step does not produce a new layer. Treatments with less Diborane works too, it may be necessary then to increase the treatment time. Similarly, larger Diborane flows may further reduce the treatment time. The process pressure is usually in the range 0.1 to 1 mbar. The process temperature is not changed from the one used for ZnO deposition.

Step 4 of the example treatment process is to pump the process chamber or purge it, similarly to step 2.

Step 5 of the example treatment is to start with growth of the successive ZnO fill layers in the same LPCVD process environment.

Variations to the general treatment process may be made to achieve desired results. For example, step 4 is recommended if the successive layer should be deposited without any Diborane doping, otherwise it can be skipped. In addition, steps 2 and 3 can be replaced by just purging the chamber with the Diborane/water mixture specified in step 4 for a longer time. Generally, it is just important to reduce the amount of DEZ enough to stop ZnO growth. Further, by using large flows of Diborane (>1000 sccm) it is possible to skip steps 2 and 4. Treatment then becomes: stop DEZ (step 1), introduce large Diborane flow (former step 3), continue deposition (former step 5).

The ratio of water to Diborane flows can be theoretically optimized by considering that one Diborane molecule can react with six water molecules to produce boric acid and hydrogen. According to:

B₂H₆+6H₂O=2B(OH₃)+6H₂.

Considering the Diborane concentration of 2% in H₂, for a given Diborane flow x, the theoretically optimized water flow is around 0.12x. (e.g. for a flow of 1000 sccm Diborane, water flow should be approximately 120 sccm—thus water/Diborane ratio 0.12). Larger amounts of water may reduce the effectiveness of the treatment requiring a longer treatment time.

FIG. 8 is a graph showing results of experiments performed to optimize the water to Diborane ratio in accordance with embodiments of the invention. In the experiment, TCO front contacts of the second type (described below) were prepared using 22 ZnO layers, each one separated by a surface treatment from the previous layer. For the surface treatment, Diborane flow was set to 2500 sccm, water flow was varied; and treatment time was set to 10 s.

As seen in FIG. 8, the haze, as an important property of the resulting layer, is not too sensitive to water flow in the range shown above. However, for the given set of parameters a flow of 300 sccm water vapor has shown to result in lowering the haze. Generally, the TCO layer contains a first “seed” layer, followed by a thicker, second “bulk” layer. The first layer has a high dopant concentration, and the second layer has a low dopant concentration. In doing so, the electrical properties of the TCO are separated from the optical properties of the TCO. High doping in the thin first layer provides improved conductivity, lower sheet resistance, and low doping in the second thicker layer assists with greater haze. The one or more fill layers deposited on the second “bulk” layer “smooth” the interface between the TCO and the subsequent layers, and in doing so, improve the performance of the cell, i.e., reduced defect/crack formation due to the smoother interface.

As a consequence of this Diborane treatment, ZnO growth will restart independently of the underlying ZnO structures. Several alternative methods to perform the Diborane treatment exist. That is, the fill layer will not have the same crystallite path as the base layer.

Embodiments of the invention may be implemented as an inline process with a treatment curtain. In a system used for LPCVD comprising e.g. two deposition chambers it is possible to add an additional subsystem between the first and the second deposition chamber. The additional subsystem (e.g. an independent gas mixture injection system) injects a controlled flow of Diborane and water (flows similar as above) in the vacuum chamber. When the substrates are transferred from one deposition chamber to the next, the TCO surface grown in the first chamber is treated with a Diborane/water mixture according to the invention. When TCO growth is continued in the second chamber, new crystals start to grow as described before.

Embodiments of the invention may be implemented as a multi-chamber system. For example, if the deposition system comprises more than two chambers, the treatment subsystem can be placed between any of the deposition chambers. Depending on the number of treatment subsystems and depending on their positions, it is possible to achieve discrete thickness ratios between TCO layers. Additionally, tuning the treatment and purging times allows controlling the thickness of the deposited TCO layers.

Embodiments of the invention may also be implemented as separate machines. For example, the treatment can be performed as last step in the first machine, then the substrate is exposed to air and then the deposition is continued within a second machine. Even in this case layer growth restarts from new seeds. (Experiments have shown that without treatment layer growth continues along existing crystallites). Alternatively, the treatment can be performed at the beginning on the deposition in the second machine. Similarly, substrates can be fed to the same machine after a first deposition to receive an additional coating.

Another alternative procedure involves wet chemistry treatment. For example, the TCO coated glasses may be treated with a diluted boric acid solution. (It may even work with other diluted acids or bases). This is an alternative to process step 3 of the general treatment process described above.

Alternative treatments involve ZnO growth regime treatment. For example, an alternative procedure leading to similar results as a Diborane treatment uses a thin layer of ZnO grown at completely different conditions than the previous layer. It is possible to strongly increase the water to DEZ flow ratio (more water than DEZ, e.g. 5 times more water than DEZ or more); this will deposit a thin layer of ZnO which will disturb growth of the following ZnO layers grown using a Water/DEZ <=2. Similarly, if the ZnO surface temperature is changed, ZnO growth is disturbed and it is possible to achieve an effect similar to using a Diborane treatment.

As an alternative, it is possible to grow a thin layer with diborane/DEZ ratio>=1, however such extremely doped layer may disturb the growth of the following layers.

Several types of front contacts (FC) can be realized in accordance with embodiments of the invention. All variations of the front contact embodiment includes a base, rather thick ZnO layer used to scatter light, and then a certain number of fill layers with different thicknesses are used to improve cell growth.

First Type of FC:

1. A LPCVD ZnO layer of thickness from 1 μm to 4 μm with Haze >20%. Best: thickness between 1.4 μm and 3 μm, Haze >25%.

2. Perform a treatment to disturb growth of ZnO (described in U.S. 61/379,917 and derived applications).

3. Deposit several thin (much thinner than the base layer, e.g. less than 500 nm, best 60 nm to 250 nm) ZnO layer followed by a surface treatment as in point 2.

First Type of FC, First Variation:

1. A multilayer ZnO as described in PCT/EP2012/050479 (which is incorporated herein by reference in its entirety) with Haze >20%.2.

2. Perform a treatment to disturb growth of ZnO (described in U.S. 61/379,917 and the derived applications noted above).

3. Deposit several thin (much thinner than the base layer, e.g. less than 500 nm, best 60 nm to 250 nm) ZnO layer followed by a surface treatment as in point 2.

First Type of FC, Second Variation:

1. A ZnO (multi)layer with Haze >20% as above.

2. Perform a treatment to disturb growth of ZnO.

3. Deposit a series of ZnO layer with decreasing thickness starting from one half of the total thickness of the base layer. After each layer perform a surface treatment.

FIG. 9 is a simplified sketch based on decreasing thickness of fill layers. The layer on the bottom represents a thick ZnO layer. Then the surface is treated with Diborane. Thinner layers on ZnO are then deposited on top. After each layer, a Diborane treatment is performed. In this example the thickness of each layer decreases continuously from one layer to the next. This is not a strict requirement. It may be helpful, but not necessary

First Type of FC, Third Variation:

1. A ZnO (multi)layer with Haze >20% as above.

2. Perform a treatment to disturb ZnO growth.

3. Deposit at least one ZnO layer with thickness lower than the total thickness of the base layer but thicker than the fill layer mentioned in the first embodiment.

4. Perform a surface treatment.

5. Deposit at least one thin layer (<300 nm, best 30 nm to 200 nm)

Second Type of FC:

Directly on the glass substrate, deposit at least two ZnO layers of thickness below 1 μm (good 10 nm to 300 nm, best 50 nm to 150 nm) each followed by a surface treatment as in the first type, point 2. In this case, especially if the thickness of each layer is 50 nm to 150 nm, the result will be a rather flat ZnO layer with low haze. A reasonable total thickness is larger than 500 nm, good range 1 μm to 2 μm. Increasing the number of the layers (keeping the thickness of each sublayer constant) allows to control the sheet resistance of the resulting layer stack (a thicker layer will have a lower sheet resistance like in normal single layer ZnO). Sheet resistance can be controlled by changing the doping of each sub-layer too. Haze can be controlled by changing the thickness of each sub-layer (thicker sub-layers will increase the total haze, thinner sub-layers will decrease the total haze). Using this type of front contact it is possible to produce layer with nominally zero haze and a wide range of sheet resistance.

Third Type of FC:

1. Directly on the glass substrate, deposit at least two ZnO layers of thickness below 1 μm (good 10 nm to 500 nm, best 60 nm to 150 nm) each followed by a surface treatment as in the first embodiment, “point 2.”

2. Deposit (with or without treatment) a thicker ZnO layer (thickness >500 nm, good range 1 μm to 2 μm). All embodiments mentioned in Types 1 and 2 above could then be deposited on top of such a thicker ZnO layer.

In this case, the resulting layer will have a rough surface as in “normal” single layer ZnO or simple (conventional) multilayer systems. The Rsq (ohms SQUARE) of the layer stack can be controlled by modifying the number and the thickness of the layers deposited in step 1. The surface morphology can then be controlled with the other approaches mentioned above.

All layer combinations presented above could be used as back contacts too. Especially the second example (rather flat layers) may be interesting to produce back contacts with low roughness which may be more resistant against degradation. Further, all types of front contact presented above can be combined with textured glass to control the light scattering properties or to improve cell growth. A textured glass can be smoothed by using approaches listed above as type first or second type. In this case it is possible to obtain good light scattering typical of rough textured glass combined with a rather flat interface TCO-cell with enhances cell growth.

A well-defined combination of light scattering and electrical properties can be obtained combining all above approaches (especially first or third type plus textured glass). Glass texturing can be made with rather large features (several micrometers) which are optimal for scattering red and near-infrared light. At the same time smaller structures can be produced in the TCO to scatter blue and green light by appropriately combining the sequence of ZnO layers and treatments. The desired resistivity can be achieved using the third type of Front Contact.

As noted above, characteristics of the TCO layer can strongly affect the thin-film module performance. For example, the inventors recognized that, in a p-i-n silicon solar cell, the contact between the front ZnO layer and the p layer effects a potential barrier which limits the open circuit voltage Voc of the cell. To overcome this limitation the use of a microcrystalline p layer in the cell is usually mandatory and well established in the art; however, the inventors discovered that a hydrogen plasma treatment of the ZnO front electrode improves the properties of an amorphous thin-film silicon solar cell grown on it, especially thus avoiding a microcrystalline player.

According to one embodiment of the hydrogen treatment feature, a film solar cell may be produced by depositing, on a substrate, a transparent conductive oxide layer, exposing a surface of the transparent conductive layer to a hydrogen plasma and growing a p-doped amorphous silicon layer on the plasma treated transparent conductive layer. Thereafter, an intrinsic amorphous silicon absorber layer may be grown on the a-Si p-layer.

In one embodiment, the transparent conductive layer is a ZnO layer and the plasma treatment is performed at the following parameters:

Treatment time: 2-20 min, preferably 2-10 min and further preferred 2-5 min.;

Pressure: about 2 mBar;

Plasma Power: 400 W RF power; the power applied in a KAI-M PECVD Plasma rector (commercially available from Orleiker Solar) at 40.68 MHz; and

Substrate Temperature: 200° C.

The inventors performed an experiment in which they exposed the surface of LPCVD ZnO layers deposited under various conditions (type A to D) in a Kai M reactor with a plasma of hydrogen (H₂). The parameters applied during the plasma process were:
H₂ gas flow 1800 sccm,
pressure: 2 mBar,
power: 400 W, and
temperature: 200° C.

Effect of the Treatment on LPCVD ZnO Layers

Table 1 shows the sheet resistances of ZnO layers before and after hydrogen plasma exposure. As seen, for all the layers a decrease of the sheet resistance down to about 10 to 15 Ohms square is measured after hydrogen plasma exposure. Further, as seen for all types, hydrogen treatment provided a decrease in sheet resistance of at least 10%.

TABLE 1
Sheet resistance of four type of LPCVD ZnO layers before and after
hydrogen plasma treatment.

| ZnO layer | Type A | Type B | Type C | Type D |
|---|---|---|---|---|
| Sheet resistance before treatment | 54 | 30 | 69 | 12 |
| [Ohms square] | | | | |
| Sheet resistance after treatment | 15 | 10 | 11 | 10 |
| [Ohms square] | | | | |

NOTE
Type A is low doping, and Type D is high doping (A-D → trend is increasing dopant concentration and different TCO thickness. I think Type C is lower dopant concentration and thinner. I have requested the specs. for these properties from the inventor.)

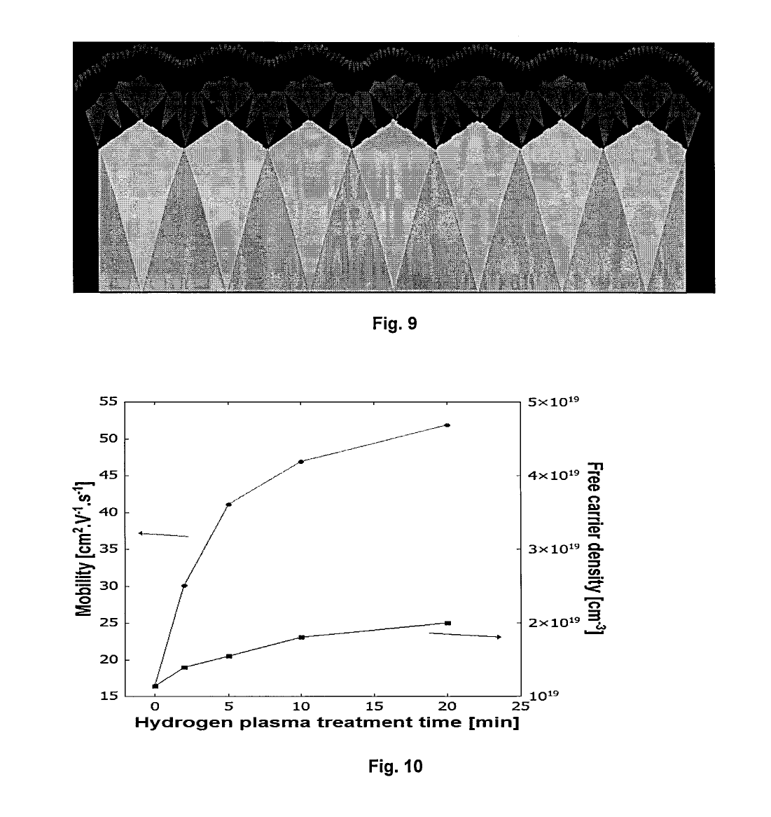

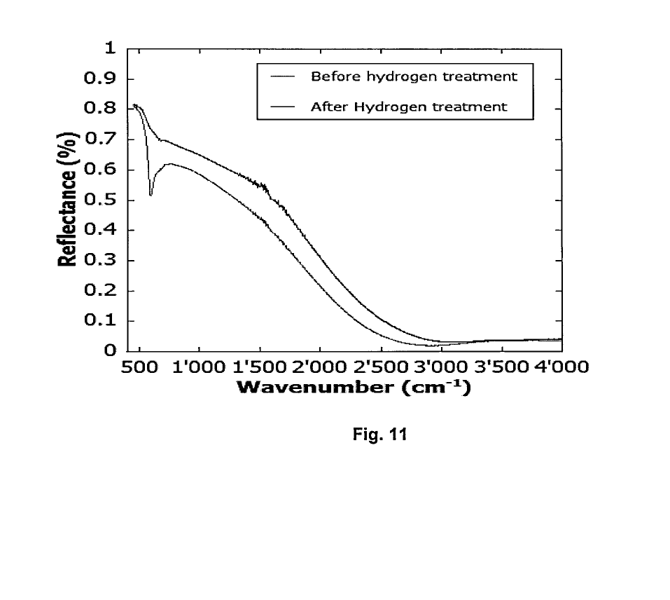

FIG. 10 shows the free electron mobility and the free carrier density of a LPCVD ZnO film as a function of the hydrogen plasma exposure time. A continuous increase of both mobility and carrier density is measured with the increasing hydrogen plasma exposure time. Depending on the plasma parameters faster treatment could be achieved.

FIG. 11 shows the infrared reflectance of a LPCVD ZnO film before and after hydrogen plasma exposure. As seen, there was shift of the curve toward higher wavenumber, indicating an increase in the free carrier density after plasma exposure. We also observed the disappearance of a peak located around 580 cm⁻¹, the disappearance of this peak constitutes an indicator that the plasma treatment is effective.

Effect of the Treatment on Solar Cells

Table 2 shows the open circuit voltage of amorphous silicon solar cells grown on LPCVD ZnO substrate exposed and non exposed to an hydrogen plasma. The amorphous cells presented here include an amorphous p layer and not microcrystalline p layer. A Voc improvement of 10 to 20 mV is measured on cell deposited on hydrogen plasma exposed LPCVD ZnO substrates, compared to cell deposited on a similar substrate not exposed to hydrogen plasma. The ZnO layers exposed to hydrogen plasma lead to an improved ZnO-doped-Si layers interface.

TABLE 2
Open circuit voltage of amorphous solar cells with and without hydrogen
plasma treatment

| Solar Cell | Type A | Type B | Type C | Type D |
|---|---|---|---|---|
| ZnO layer | Type A | Type A | Type D | Type D |
| Open circuit voltage without | 872 | 854 | 870 | 883 |
| treatment [Volts] | | | | |
| Open circuit voltage with treatment | 894 | 875 | 897 | 891 |
| [Volts] | | | | |

Further advantages of the above-described hydrogen plasma treatment may also be realized. For example, the sheet resistance of the ZnO layers Is improved by the plasma exposure. In addition, long term and damp heat stability of the ZnO layers could be improved by the plasma exposure. Further, the ZnO layers and the ZnO-doped-Si layer interfaces are improved when exposing the back contact of a solar cell to the hydrogen plasma. Still further, an H-plasma treatment of back contact can be also applied effectively to micromorph and triple junction devices having ZnO as a back contact.

Having now described embodiments of the present invention, it should be apparent to those skilled in the art that the foregoing is merely illustrative and not limiting, having been presented by way of example only. Thus, although particular configurations have been discussed and illustrated herein, other configurations can also be employed. Numerous modifications and other embodiments (e.g., combinations, rearrangements, etc.) are enabled by the present disclosure and are within the scope of one of ordinary skill in the art, and are contemplated as falling within the scope of the disclosed subject matter and any equivalents thereto. Features of the disclosed embodiments can be combined, rearranged, omitted, etc., within the scope of the invention to produce additional embodiments. Furthermore, certain features may sometimes be used to advantage without a corresponding use of other features. Accordingly, Applicants intend to embrace all such alternatives, modifications, equivalents, and variations that are within the spirit and scope of the present invention.

What is claimed:

1. A method for fabricating a thin film solar device, comprising:
providing a substrate having a transparent conductive oxide (TCO) layer deposited on a surface of the substrate, said TCO layer having an as deposited sheet resistance; and
exposing at least a portion of a surface of said TCO layer to a hydrogen plasma under conditions which result in a treated TCO layer having a reduced sheet resistance which is at least 10% less than the as deposited sheet resistance.

2. The method of claim 1, wherein said providing comprises depositing a ZnO layer on the surface of said substrate.

3. The method of claim 1, further comprising depositing a silicon layer on the treated TCO layer.

4. The method of claim 2, wherein said exposing comprises exposing the ZnO layer to said hydrogen plasma for a time duration ranging from about 2 minutes to about 20 minutes.

5. The method of claim 4, wherein said time duration ranges from about 2 minutes to about 10 minutes.

6. The method of claim 5, wherein said time duration ranges from about 2 minutes to about 5 minutes.

7. The method of claim 2 wherein said exposing comprises exposing under a pressure condition of about 2 mBar.

8. The method of claim 2, wherein said exposing comprises exposing the ZnO layer under a power condition of 400 W RF power at 40.68 MHz.

9. The method of claim 8, wherein said exposing comprises exposing the ZnO layer under a condition of 200° C. substrate temperature.

10. The method of claim 2, wherein said exposing comprises exposing the ZnO layer under a condition of an H₂ flow rate of about 1800 sccm.

11. The method of claim 2, wherein said exposing results in the treated ZnO layer having a reduced sheet resistance of from 10 to 15 ohms square.

12. The method of claim 2, wherein:
said depositing comprises depositing a ZnO layer having an as deposited sheet resistance of from 12 to 54 ohms square; and
said exposing results in a treated ZnO layer having a reduced sheet resistance of from 10 to 15 ohms square.

13. The method of claim 2, further comprising controlling an exposure time of the ZnO layer based on an observed continuous increase in free electron mobility with increased H₂ plasma treatment time.

14. The method of claim 2, further comprising controlling an exposure time of the ZnO layer based on an observed continuous increase in free carrier density with increased H₂ plasma treatment time.

15. The method of claim 2, wherein said conditions include pressure, plasma power, and substrate temperature, the method further comprising varying at least one of said conditions to increase infrared reflectance of said ZnO layer to a higher wavenumber.

16. The method of claim 2, further comprising forming an amorphous silicon solar cell on said treated the ZnO layer, the amorphous silicon cell including a p-doped amorphous silicon layer and not including a p-doped microcrystalline silicon layer.

17. The method of claim 16, wherein said exposing enhances the properties of the amorphous silicon solar cell such that there is an increase of voltage open-circuit (V_{oc}) when compared to an amorphous silicon cell that did not undergo said exposing.

18. The method of claim 18, wherein the increase of V_{oc} is an increase of from 10 to 20 mV over a V_{oc} of the amorphous silicon solar cell that did not undergo said exposing.

19. The method of claim 16, wherein said amorphous silicon solar cell comprising two or more p-i-n junctions.

20. The method of claim 2, wherein said exposing substantially improves damp heat stability of the ZnO.
